(19) United States
(12) Patent Application Publication
(10) Pub. No.: US 2006/0195762 A1
(43) Pub. Date: Aug. 31, 2006

(54) HS-DSCH transmitter and CRC calculator therefor in a W-CDMA system

(75) Inventor: Dae-Whan Back, Seoul (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/362,878

(22) Filed: Feb. 28, 2006

(30) Foreign Application Priority Data
Feb. 28, 2005 (KR) 2005-16695

(51) Int. Cl. H03M 13/00

(52) U.S. Cl. 714/758

(57) ABSTRACT

An HS-DSCH transmitter in a W-CDMA system is provided. In the HS-DSCH transmitter, a memory stores input transmission data. A bit scrambling code ROM stores random sequences for bit scrambling of the input data. A CRC calculator generates a bit scrambled sequence by attaching a CRC to the input transmission data and multiplying the CRC-attached data by a random sequence read from the bit scrambling code ROM. First and second turbo encoder input memories store the bit scrambling sequence. A turbo encoder & rate matcher reads the same bit scrambling sequence from the first and second encoder input memories, generates a systematic sequence, a first parity sequence, and a second parity sequence by turbo-encoding the read bit scrambling sequence, and rate-matches the sequences. First, second and third rate matching memories store the rate-matched sequences, respectively.

### CROSS-REFERENCE TO RELATED APPLICATION

This application claims the benefit under 35 U.S.C. § 119(a) to a Korean patent application entitled “HS-DSCH Transmitter and CRC Calculator Therefor in a W-CDMA System” filed in the Korean Intellectual Property Office on Feb. 28, 2005 and assigned Ser. No. 2005-16695, the entire contents of which are hereby incorporated by reference.

### BACKGROUND OF THE INVENTION

1. Field of the Invention

The present invention relates to a Wideband-Code Division Multiple Access (W-CDMA) system. In particular, the present invention relates to an apparatus for processing High-Speed Downlink Shared CHannel (HS-DSCH) symbols in a High Speed Downlink Packet Access (HSDPA) modem.

2. Description of the Related Art

A 3^{rd} generation mobile communication system using W-CDMA based on the European Global System for Mobile communications (GSM) system, Universal Mobile Telecommunication Service (UMTS) provides mobile subscribers or computer users with a uniform service of transmitting packet-based text, digitized voice, and video and multimedia data at or above 2 Mbps irrespective of their locations around the world. With the introduction of the concept of virtual access, the UMTS system allows for access to any end point within a network all the time. The virtual access refers to packet-switched access using a packet protocol like Internet Protocol (IP).

HSDPA introduces Adaptive Modulation and Coding (AMC), Hybrid Automatic Repeat Request (HARQ), and Scheduling in order to provide high-speed downlink data service at up to 14 Mbps in theory. In HSDPA, an HS-DSCH comprises a transport channel for high-speed data transmission, and a High Speed-Shared Control CHannel (HS-SCCH) delivers control information about a High Speed-Physical Downlink Shared CHannel (HS-PDSCH) to which the HS-DSCH is mapped.

The HS-DSCH and the HS-SCCH are transmitted together all the time. A User Equipment (UE) decodes the HS-DSCH after receiving the HS-SCCH because the HS-SCCH provides control information needed for receiving the HS-DSCH. Therefore, a Node B transmits the HS-DSCH two slots after transmission of the HS-SCCH.

For mapping of the HS-DSCH to the HS-PDSCH, Cyclic Redundancy Code (CRC) calculation, bit scrambling, channel encoding, and rate matching are to be sequentially performed. At a typical hardware operation clock frequency of 61.44 MHz, 81,920 clock cycles exist for two slots according to the W-CDMA standards.
61.44 MHz=chip rate×16 clocks
1 slot=10 symbols
1 symbol=256 chips
1 chip=16 clocks
1 slots×10 symbols×256 chips×16 clocks=81,920 clocks.

In W-CDMA, a transport block size for transmission on the HS-DSCH is 137 to 28800 bits. Hence, to map a transport block to the physical channel, a total of 144,096 clock cycles are required.
The number of clock cycles for CRC calculation: 28,800
The number of clock cycles for bit scrambling: 28,824
The number of clock cycles for turbo encoding: 57,648
The number of clock cycles for rate matching: 28,824

Thus, it is not possible to sequentially perform CRC calculation, bit scrambling, channel coding, and rate matching on an input sequence having up to 28800 bits within 2 slots.

### SUMMARY OF THE INVENTION

An object of the present invention is to substantially solve at least the above problems and/or disadvantages and to provide at least the advantages below. Accordingly, the present invention provides a symbol processing apparatus for mapping the HS-DSCH to the HS-PDSCH.

The present invention also provides a symbol processing apparatus for performing CRC calculation, bit scrambling, channel coding, and rate matching within 2 slots during processing HS-DSCH symbols.

The present invention also provides a CRC calculator for high-speed symbol processing.

According to one aspect of the present invention, in an HS-DSCH symbol process in a W-CDMA system, a memory stores input transmission data. A bit scrambling code ROM stores random sequences for bit scrambling of the input data. A CRC calculator generates a bit scrambled sequence by attaching a CRC to the input transmission data and multiplying the CRC-attached data by a random sequence read from the bit scrambling code ROM. First and second turbo encoder input memories store the bit scrambling sequence. A turbo encoder & rate matcher reads the same bit scrambling sequence from the first and second encoder input memories, generates a systematic sequence, a first parity sequence, and a second parity sequence by turbo-encoding the read bit scrambling sequence, and rate-matches the sequences. First, second and third rate matching memories store the rate-matched sequences, respectively.

According to another aspect of the present invention, in a CRC calculator for high-speed data processing in a communications system, an N-bit parallel CRC calculator calculates a first M-bit CRC for part of input data being a multiple of N bits. An exclusive-OR operator exclusive-OR operates the first CRC with every following N bits of the input data. A first multiplexer provides first N bits of the input data to the N-bit parallel CRC calculator and then provides the output of the exclusive-OR operator to the N-bit parallel CRC calculator. A second multiplexer serially provides the remainder of dividing the input data by N bits, bit by bit. A serial CRC calculator receives the first CRC from the N-bit parallel CRC calculator after the part of the input data being a multiple of N bits is provided to the N-bit parallel CRC calculator, calculates a second CRC for the bits received from the second multiplexer, and outputs a final CRC for the input data by combining the second CRC with the first CRC.

### BRIEF DESCRIPTION OF THE DRAWINGS

The above and other objects, features and advantages of the present invention will become more apparent from the following detailed description when taken in conjunction with the accompanying drawings in which:

FIG. 1 is a flowchart illustrating a procedure for mapping the HS-DSCH to the HS-PDSCH in a conventional W-CDMA system;

FIG. 2 is a block diagram of an HS-DSCH symbol processor according to an exemplary embodiment of the present invention;

FIG. 3 is a block diagram of a CRC calculator according to an exemplary embodiment of the present invention;

FIG. 4 is a block diagram of a turbo encoder in a turbo encoder & rate matcher according to an exemplary embodiment of the present invention; and

FIG. 5 is a block diagram of a rate matcher in the turbo encoder & rate matcher according to an exemplary embodiment of the present invention.

Throughout the drawings, like reference numerals will be understood to refer to like parts, components and structures.

### DETAILED DESCRIPTION OF EXEMPLARY EMBODIMENTS

Exemplary embodiments of the present invention will be described herein below with reference to the accompanying drawings. In the following description, well-known functions or constructions will be omitted for clarity and conciseness.

The main feature of an exemplary embodiment of the present invention lies in that functions required from the 3GPP TS25.212 specification are implemented using a reduced number o hardware cycles and an optimized hardware structure in encoding HS-DSCH symbols, for HSDPA service in a W-CDMA system.

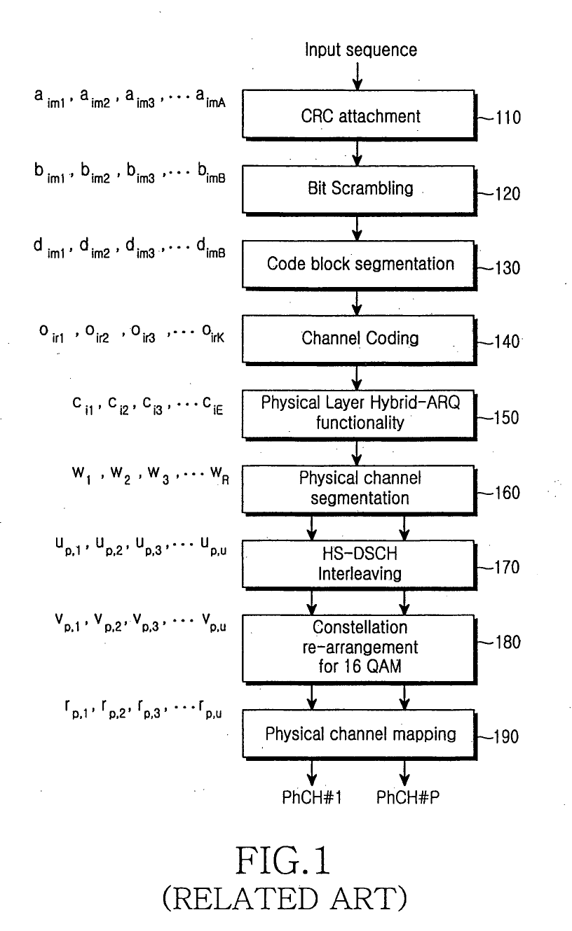

FIG. 1 is a flowchart illustrating a procedure for mapping the HS-DSCH to the HS-PDSCH in a conventional W-CDMA system.

Referring to FIG. 1, a transport block A [aᵢₘ₁, aᵢₘ₂, aᵢₘ₃, . . . , a_{imA}] to be transmitted on the HS-DSCH is an input sequence for HS-DSCH symbol processing. In step 110, a 24-bit CRC is calculated and attached to the input sequence. The resulting sequence B [bᵢₘ₁, bᵢₘ₂, bᵢₘ₃, . . . , b_{imB}] is scrambled on a bit-by-bit basis, thus creating a bit scrambled sequence D [dᵢₘ₁, dᵢₘ₂, dᵢₘ₃, . . . , d_{imD}] in step 120. In step 130, if the bit scrambled sequence D exceeds 5114 bits, it is segmented into code blocks O [oᵢᵣ₁, oᵢᵣ₂, oᵢᵣ₃, . . . , o_{irK}], considering the nature of turbo encoding. In step 140, the code blocks o are individually turbo-encoded to code sequences C [cᵢ₁, cᵢ₂, cᵢ₃, . . . , c_{iE}]. The code sequences C are buffered to support physical layer HARQ in step 150.

In step 160, an intended sequence W [w₁, w₂, w₃, . . . w_{R}] is read among the buffered code sequences and segmented into physical channel sequences U [u_{p,1}, u_{p,2}, u_{p,3}, . . . , u_{p,U}] to be mapped onto P physical channels. The physical channel sequences U are interleaved in step 170. Constellation rearrangement for 16-ary Quadrature Amplitude Modulation (16QAM) is performed on the interleaved sequences V [v_{p,1}, v_{p,2}, v_{p,3}, . . . , v_{p,U}] in step 180. In step 190, the rearranged sequences R [r_{p,1}, r_{p,2}, r_{p,3}, . . . , r_{p,U}] are mapped to physical channel frames and transmitted on P HS-PDSCHs.

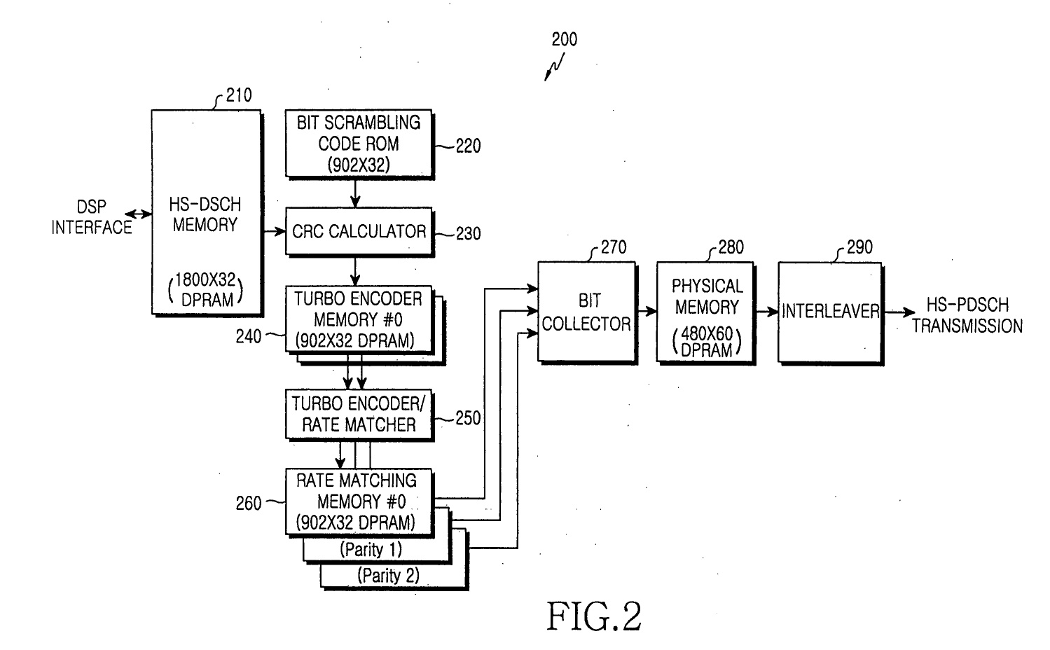

FIG. 2 is a block diagram of an HS-DSCH symbol processor according to an exemplary embodiment of the present invention.

Referring to FIG. 2, an HS-DSCH symbol processor 200 comprises an HS-DSCH memory 210, a bit scrambling code Read Only memory (ROM) 220, a CRC calculator 230, turbo encoder input memories (#0 and #1) 240, a turbo encoder & rate matcher 250, rate matching memories (#0, #1, and #2) 260, a bit collector 270, a physical memory 280, and an interleaver 290.

The HS-DSCH symbol processor 200 receives HS-DSCH data from a Digital Signaling Processor (DSP) and a Central Processing Unit (CPU) at a higher layer through the HS-DSCH memory 210. Because a maximum data block size for processing is 28800 bits, the HS-DSCH memory 210 is an 1800×32 Dual Port Random Access Memory (DPRAM), for real-time processing.

The CRC calculator 230 performs both CRC attachment and bit scrambling in compliance with the W-CDMA standards. The CRC calculator 230 attaches a 24-bit CRC to the HS-DSCH data, multiplies the CRC-attached data by a random sequence received from the bit scrambling code ROM 220, and stores the product in the turbo encoder input memories 240 at the same time. The bit scrambling code ROM 220 stores preliminarily generated random sequences and provides them to the CRC calculator 230, thereby the number of total hardware cycles needed for symbol processing. The bit scrambling code ROM 220 is of a 902×32 size, taking into account of the maximum data size 28800 bits and the 24-bit CRC.

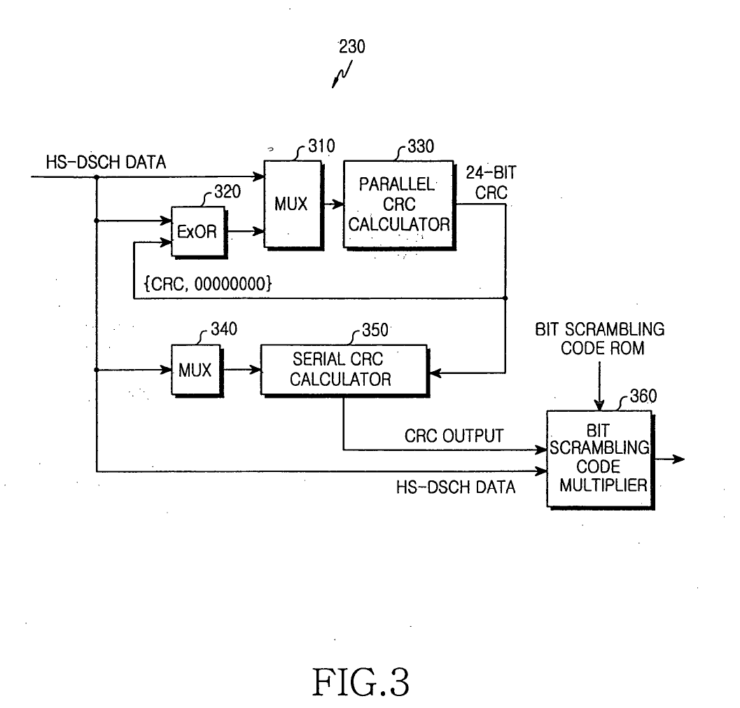

The CRC calculator 230 utilizes 32-bit parallel CRC calculation and serial CRC calculation to reduce the number of hardware cycles. If the size of the HS-DSCH data is not a multiple of 32 bits, a CRC is calculated for part of the HS-DSCH data being a multiple of 32 bits in the parallel CRC calculation method, whereas a final 24-bit CRC is calculated for the remainder of dividing the HS-DSCH data by 32 bits. The configuration of the CRC calculator 232 is illustrated in FIG. 3, which will be described in more detail later.

The output of the CRC calculator 230 is stored in both the turbo encoder input memories 240 each being a 902×32 DPRAM because this enables rate matching without buffering turbo-coded data in the turbo encoder & rate matcher 250 and an interleaved sequence is to be provided to a second constituent encoder (not shown) of the turbo encoder & rate matcher 250. The turbo encoder & rate matcher 250 encodes the same sequences read concurrently from the turbo encoder input memories 240 by two constituent encoders (not shown) and an internal interleaver and creates three code sequences, that is, a systematic sequence, a first parity sequence, and a second parity sequence. The three code sequences are individually repeated or punctured according to a physical channel data rate, for rate matching. The rate-matched sequences are separately stored in the three rate matching memories 260, each being of a 902×32 size.

The bit collector 270 constructs a transmission sequence by collecting intended bits from the stored three rate-matched sequences according to an HARQ operation. The transmission sequence may have new bits or retransmission bits.

The physical memory 280 is a 480×60 DPRAM. It separately stores the transmission sequence, for physical channel segmentation. The interleaver 290 interleaves bits read from the physical memory 280 according to a predetermined interleaver size, for mapping to the HS-PDSCH. As illustrated in FIG. 1, the interleaved bits are subject to constellation rearrangement and physical channel mapping, prior to transmission.

FIG. 3 is a block diagram of the CRC calculator 230 according to an exemplary embodiment of the present invention. As stated before, the CRC calculator 230 utilizes both the parallel CRC calculation and the serial CRC calculation in calculating a CRC for input HS-DSCH data because the HS-DSCH data is of a variable size up to 28800 bits. Therefore, part of the HS-DSCH data for which the parallel CRC calculation is suitable is processed in a parallel CRC calculator 330, and if the HS-DSCH data still remains, the remainder is processed in a serial CRC calculator 350. The parallel CRC calculator 330 processes bit blocks having N bits each in parallel and calculates an M-bit CRC. Hereinbelow, M is 32 bits and N is 24 bits.

Referring to FIG. 3, the HS-DSCH data is provided to multiplexes 310 and 340, an exclusive-OR (ExOR) operator 320, and a bit scrambling code multiplier 360.

The MUX 310 operates as an output selector, in other words, a switch. The MUX 310 provides the first 32 bits of the HS-DSCH data to the parallel CRC calculator 330 at first and then provides the output of the ExOR operator 320 to the parallel CRC calculator 330. The parallel CRC calculator 330 calculates a 24-bit CRC for the 32-bit data by a parallel CRC calculation algorithm. 8 zeroes are padded to the end of the 24-bit CRC and then exclusive-OR operated with the next input 32-bit data in the ExOR operator 320. The exclusive-OR operation result is fed back to the parallel CRC calculator 330 through the MUX 310. The parallel CRC calculator 330 repeats its operation on a 32-bit basis, for the input of the HS-DSCH data. A final 24-bit CRC (a first CRC) from the parallel CRC calculator 330 is provided to the serial CRC calculator 350.

The MUX 340 serves as a Parallel-to-Serial (P/S) converter and a switch. The MUX 340 serially provides the remainder of dividing the HS-DSCH data by 32 bits to the serial CRC calculator 350. The serial CRC calculator 350 calculates a second 24-bit CRC for the received data and then calculates a final 24-bit CRC for the whole HS-DSCH data by combining the first CRC with the second CRC.

The generator polynominal for calculating the second CRC is given as
CRC24=D²⁴+D²³+D⁶+D⁵+D+1

The serial CRC calculator 350 which uses the above polynomial has 24 flip-flops concatenated serially. The outputs of flip-flops corresponding to the coefficients of the polynomial, that is, the outputs of flip-flops #24, #23, #6, #5 and #0 are connected to the ExOR operator. For the serial input of 32 data bits to the serial CRC calculator 350, the outputs of the 24 flip-flops become a second 24-bit CRC.

The parallel CRC calculator 330 receives 32 bits in parallel and updates a first 24-bit CRC for the input of the 32 bits. While the serial CRC calculation takes up to 32 clocks to output the second CRC, one clock is sufficient for the parallel CRC calculation.

The bit scrambling code multiplier 360 attaches the final 24-bit CRC received from the serial CRC calculator 350 to the HS-DSCH data, multiplies the CRC-attached data by a random sequence received from the bit scrambling code ROM 220, and outputs the resulting bit scrambled sequence to the turbo encoder input memories 240.

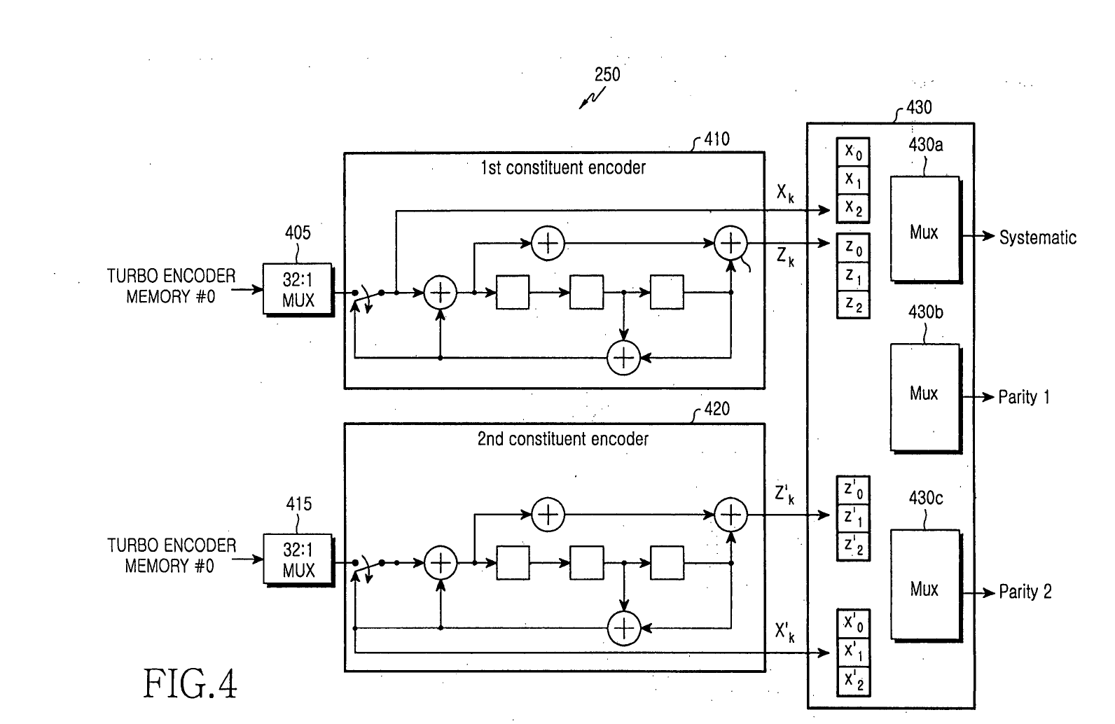

FIG. 4 is a block diagram of the turbo encoder in the turbo encoder & rate matcher 250 according to an exemplary embodiment of the present invention.

Referring to FIG. 4, 32:1 MUXes 405 and 415 operate as P/S converters. The 32:1 MUX 405 provides a 32-bit sequence sequentially read from turbo encoder input memory #0 bit by bit to a first constituent encoder 410, and the 32:1 MUX 415 provides a 32-bit sequence read from turbo encoder input memory #0 according to an interleaving pattern bit by bit to a second constituent encoder 420. The first constituent encoder 410 creates systematic bits Xₖ and parityl bits Zₖ by encoding the received sequence. Similarly, the second constituent encoder 420 creates systematic bits X′ₖ and parity2 bits Z′ₖ by encoding the received sequence.

A trellis terminator 430 arranges the bits received from the first and second constituent encoders 410 and 420 through MUXes 430a, 430b and 430c according to the types of the bits and outputs a systematic sequence, a first parity sequence, and a second parity sequence. To be more specific, the MUX 430a creates the systematic sequence by concatenating the systematic bits received form the first constituent encoder 410. The MUX 403b creates the first parity sequence by concatenating the first parity bits received from the first constituent encoder 410. The MUX 430c creates the second parity sequence by concatenating the second parity bits received from the second constituent encoder 420.

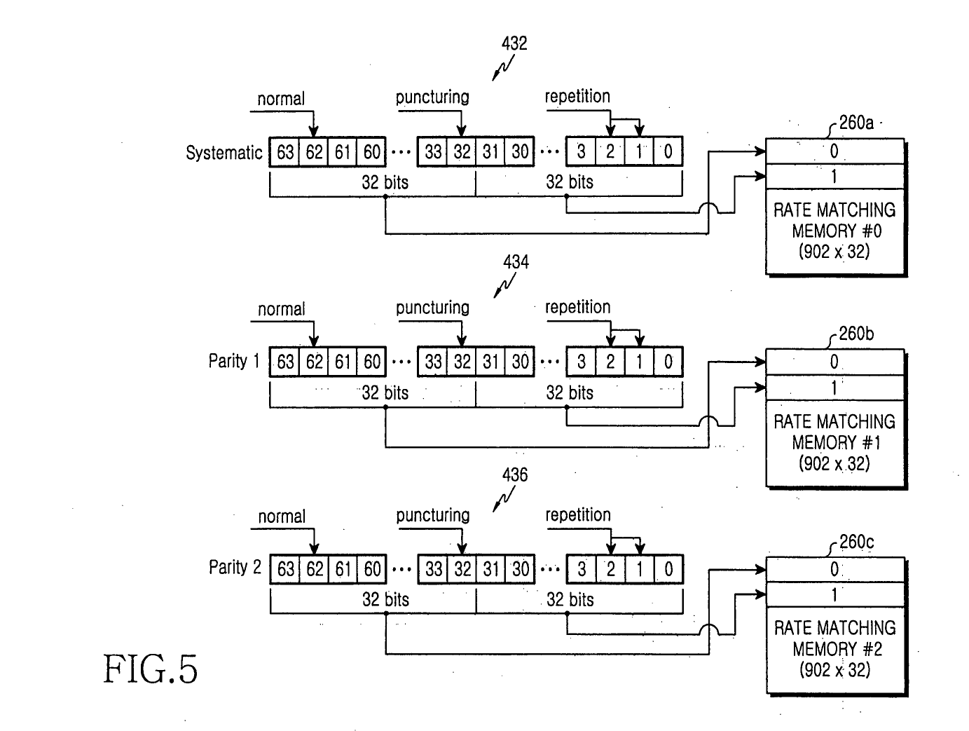

FIG. 5 is a block diagram of the rate matcher in the turbo encoder & rate matcher 250 according to an exemplary embodiment of the present invention.

Referring to FIG. 5, the code sequences from the trellis terminator 430 are subject to rate matching, for transmission on a physical channel. The turbo encoder & rate matcher 250 determines whether to simply pass, repeat or puncture the bits of the code sequences by a predetermined rate matching algorithm and sequentially stores the bits in 64-bit registers 432, 434 and 436 according to the determination. Each time a bit is stored in the registers 432, 434 and 436, a pointer pointing a bit position at which the bit will be stored in the rate matching memories 260a, 260b and 260c is increased by 1. A bit to be punctured is not stored and thus the pointer is not increased. A bit to be repeated is stored at the current and next bit positions in the registers 432, 434 and 436 and the pointer is increased by 2. The bits stored in the registers 432, 434 and 436 are shifted to corresponding rate matching memories on a 32 bit-by-32 bit basis. Consequently, the whole rate-matched sequences are stored in the rate matching memories 260a, 260b and 260c.

As described above, the CRC calculation and bit scrambling structure and the turbo encoding and rate matching structure according to an exemplary embodiment of the present invention require the following hardware clock cycles in processing HS-DSCH symbols:
the number of cycles for CRC calculation and bit scrambling: 900; and
the number of cycles for turbo encoding and rate matching: 28824.

Therefore, the symbol processor of an exemplary embodiment of the present invention can effectively process data of a variable transport block size ranging form 137 to 28800 bits within 81920 cycles equivalent to two slots.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A symbol processor for a high-speed downlink shared channel (HS-DSCH) in a wideband-code division multiple access (W-CDMA) system, the system processor comprises:
a memory for storing input transmission data;
a bit scrambling code read only memory (ROM) for storing random sequences for bit scrambling of the input transmission data;
a cyclic redundancy code (CRC) calculator for generating a bit scrambled sequence by attaching a CRC to the input transmission data and multiplying the CRC-attached data by a random sequence read from the bit scrambling code ROM;
a first turbo encoder input memory and a second turbo encoder memory, each for storing the bit scrambling sequence;
a turbo encoder & rate matcher for reading the same bit scrambling sequence from the first and second encoder input memories, generating a systematic sequence, a first parity sequence, and a second parity sequence by turbo-encoding, the read bit scrambling sequence, and rate-matching the systematic sequence, the first parity sequence, and the second parity sequence; and
first, second and third rate matching memories for storing the rate-matched sequences, respectively.

2. The symbol processor of claim 1, wherein the CRC calculator calculates a CRC for part of the input data being a multiple of a predetermined bit number by parallel CRC calculation and calculates a CRC for the remainder of dividing the input data by the predetermined bit number by serial CRC calculation.

3. The symbol processor of claim 1, wherein the CRC calculator comprises:
a 32-bit parallel CRC calculator for calculating a parallel CRC for part of the input data being a multiple of 32 bits by parallel CRC calculation;
an exclusive-OR operator for exclusive-OR operating the parallel CRC with every following 32 bits;
a first multiplexer for providing first 32 bits of the input data to the parallel CRC calculator and then providing the output of the exclusive-OR operator to the parallel CRC calculator;
a second multiplexer for serially providing the remainder of dividing the input data by 32 bits, bit by bit; and
a serial CRC calculator for receiving the parallel CRC from the parallel CRC calculator after the part of the input data being a multiple of 32 bits is provided to the parallel CRC calculator, calculating a serial CRC for the bits received from the second multiplexer, and outputting a final CRC for the input data by combining the serial CRC with the parallel CRC.

4. The symbol processor of claim 3, further comprising a bit scrambling code multiplier for generating the bit scrambled sequence by multiplying the input data attached with the final CRC by the random sequence and outputting the bit scrambled sequence to the turbo encoder input memories.

5. The symbol processor of claim 1, wherein the turbo encoder & rate matcher comprises:
a first multiplexer for sequentially reading bits of the bit scrambling sequence from the first turbo encoder input memory;
a first constituent encoder for generating systematic bits and first parity bits by encoding the bits received from the first multiplexer;
a second multiplexer for reading the bits of the bit scrambling sequence from the second turbo encoder input memory according to an interleaving pattern;
a second constituent encoder for generating interleaved systematic bits and second parity bits by encoding the bits received from the second multiplexer; and
a trellis terminator for receiving the output bits of the first and second constituent encoders and outputting the systematic sequence comprising the systematic bits, the first parity sequence comprising the first parity bits, and the second parity sequence comprising the second parity bits, separately.

6. The symbol processor of claim 5, wherein the trellis terminator comprises:
a first multiplexer for outputting the systematic bits as the systematic sequence;
a second multiplexer for outputting the first parity bits as the first parity sequence; and
a third multiplexer for outputting the second parity bits as the second parity sequence.

7. The symbol processor of claim 5, wherein the turbo encoder & rate matcher further comprises:
a first register for passing, repeating or puncturing the bits of the systematic sequence according to a predetermined rate matching algorithm and outputting the passed, repeated or punctured systematic sequence to the first rate matching memory;
a second register for passing, repeating or puncturing the bits of the first parity sequence according to the predetermined rate matching algorithm and outputting the passed, repeated or punctured first parity sequence to the second rate matching memory; and
a third register for passing, repeating or puncturing the bits of the second parity sequence according to the predetermined rate matching algorithm and outputting the passed, repeated or punctured second parity sequence to the third rate matching memory.

8. The symbol processor of claim 7, wherein each of the registers stores a bit to be passed at a predetermined bit position and increases a pointer indicating the next bit storing position by 1, stores a bit to be repeated at the predetermined bit position and the next position and increases the pointer by 2, and discards a bit to be punctured and maintains the pointer unchanged.

9. A cyclic redundancy code (CRC) calculator for high-speed data processing in a communications system, the CRC calculator comprises:
an N-bit parallel CRC calculator for calculating a first M-bit CRC for part of input data being a multiple of N bits;
an exclusive-OR operator for exclusive-OR operating the first CRC with every following N bits of the input data;
a first multiplexer for providing first N bits of the input data to the N-bit parallel CRC calculator and then providing the output of the exclusive-OR operator to the N-bit parallel CRC calculator;
a second multiplexer for serially providing the remainder of dividing the input data by N bits, bit by bit; and
a serial CRC calculator for receiving the first CRC from the N-bit parallel CRC calculator after the part of the input data being a multiple of N bits is provided to the N-bit parallel CRC calculator, calculating a second CRC for the bits received from the second multiplexer, and outputting a final CRC for the input data by combining the second CRC with the first CRC.

10. The CRC calculator of claim 9, wherein the input data comprises high-speed downlink shared channel (HS-DSCH) data in a wideband-code division multiple access (W-CDMA) system.
